(19) United States
(12) Patent Application Publication
(10) Pub. No.: US 2013/0128186 A1
(43) Pub. Date: May 23, 2013

(54) Locking Piece, Backlight Module, and LCD Device

(71) Applicants: Yicheng Kuo, Guangdong (CN); Yuchun Hsiao, Guangdong (CN); Chong Huang, Guangdong (CN); Jiahe Cheng, Guangdong (CN); Chengwen Que, Guangdong (CN); Quan Li, Guangdong (CN); Liuyang Yang, Guangdong (CN)

(72) Inventors: Yicheng Kuo, Guangdong (CN); Yuchun Hsiao, Guangdong (CN); Chong Huang, Guangdong (CN); Jiahe Cheng, Guangdong (CN); Chengwen Que, Guangdong (CN); Quan Li, Guangdong (CN); Liuyang Yang, Guangdong (CN)

(21) Appl. No.: 13/375,940

(22) PCT Filed: Nov. 29, 2011
(86) PCT No.: PCT/CN2011/083156

§ 371 Date: Dec. 2, 2011

(30) Foreign Application Priority Data
Nov. 18, 2011 (CN) 201110369649.7

(51) Int. Cl. G02F 1/13357; H05K 7/14

(52) U.S. Cl. 349/61; 248/224.8; 362/97.2

(57) ABSTRACT

The present invention discloses a locking piece, a backlight module, and an LCD device. A locking piece for fixing PCB on backplane, the fixed top of the locking piece and the PCB is provided with a clamping structure; and the root of the locking piece is provided with a fixed structure for fixing the locking piece on the backplane. Because the present invention uses independent locking pieces, the locking pieces can be selectively fixed and arranged in the positions for fixing the PCB on the backplane. Thus, the standardization and generalization design is achieved, and the cost is reduced; in addition, because a clamping structure is used between the locking piece and the PCB, compared with the modes of screw fixation, riveting fixation and the like, the clamping mode has high installation efficiency and is beneficial to productivity enhancement and further cost reduction.

### TECHNICAL FIELD

The present invention relates to the field of liquid crystal displays (LCDs), and more particularly to a locking piece, a backlight module, and an LCD device.

### BACKGROUND

An LCD device includes an LCD panel and a backlight module, wherein the bottom of the backlight module is provided with a backplane used for sealing the module and fixing a component in the module. In the existing backplanes, integral backplanes are used and are integrally formed in the mode of metal stamping or plastic injection, causing heavy products and high material cost of the products. For large-size backplanes, because larger stamping equipment is needed, the cost is higher, and because the corresponding die size is large and the structure is complicated, the die cost is also very high. With increasingly fierce market competition, it is more and more important to effectively reduce the design cost. As a result, the key research direction of each designer lies in saving the material cost and simplifying the assembly technology.

The traditional backplane is stamped and formed with hillocks for fixing components such as a printed circuit board (PCB) and the like in accordance with the requirement of different LCD devices. The processing mode for stamping and forming hillocks is inconvenient, and is difficult to achieve the standardization and generalization design of backplanes, so that the cost of backplanes is further increased.

### SUMMARY

The aim of the present invention is to provide a locking piece with the advantages of standardization, generalization and low cost, a backlight module, and an LCD device.

The aim of the present invention is achieved by the following technical schemes.

A locking piece for fixing the PCB on the backplane, the fixed top of the locking piece and the PCB is provided with a clamping structure; the root of the locking piece is provided with a fixed structure for fixing the locking piece on the backplane.

Preferably, the top of the locking piece is provided with a conical peak, and the bottom of the conical peak is extended with one or multiple buckling claws. This is one specific clamping structure. The PCB is clamped by the buckling claw(s) for fixation as long as the positioning structure of the PCB is buckled from the conical peak. The clamping mode has simple operation step and high efficiency and is beneficial to productivity enhancement.

Preferably, there are two elastic buckling claws; when the PCB is removed, the buckling claws need to be pressed and the conical peaks can be taken out; the opposite buckling claws can be conveniently pressed simultaneously for removal; meanwhile, the structures of the two buckling claws can also ensure the fixed strength.

Preferably, the structure of the fixed structure at root of the locking piece is the same as that of the clamping structure at the top. The clamping structures are adopted on both ends of the locking piece so that the universality of the locking piece is higher, and the fixation of the locking piece is achieved as long as the conical peak penetrates through the positioning structure of the backplane, and the buckling claws clamp the backplane. The clamping mode has simple operation step and high efficiency, and is beneficial to productivity enhancement.

Preferably, the fixed structure at the root of the locking piece is a rivet integrally formed with the locking piece. This is one specific fixed structure of the locking piece and the backplane.

Preferably, the fixed structure at the root of the locking piece is an integrally formed screw.

This is the other specific fixed structure of the locking piece and the backplane.

Preferably, the fixed structure at the root of the locking piece is a threaded hole. This is the third specific fixed structure of the locking piece and the backplane.

Preferably, the locking piece is integrally formed by plastics. The locking piece of the plastic structure can enhance an insulation level and avoid generating unnecessary grounding problems caused by that the PCB comes into contact with the metal backplane.

A backlight module comprises a backplane, a PCB, and the aforementioned locking piece(s) for fixing the PCB on the backplane. The backplane is provided with positioning structure(s) for fixing the locking piece, the locking piece is arranged on the backplane by the positioning structure, and the PCB is fixed on the locking piece.

Preferably, the positioning structure is a chute, and the locking piece is arranged on the backplane by the chute. This is one specific positioning structure form. The chute can provide continuous positioning and has flexible mounting position.

Preferably, the positioning structures are multiple standard mounting holes, and the locking pieces are selectively arranged on the backplane by the multiple mounting holes. This is the other specific positioning structure form. The multiple standard mounting holes facilitate to select corresponding mounting holes in accordance with actual conditions, and the positioning mode is flexible. In addition, after the locking pieces are arranged in the mounting holes, the mounting holes can effectively limit the locking pieces to move on the backplane to obtain good positioning effect.

Preferably, the backplane comprises a frame, and the frame comprises multiple mutually joined brackets. Bridges are arranged between the brackets, and the locking pieces are arranged on the bridges. This is the application of the locking pieces in a frame type backplane, and more flexible positioning positions can be provided when the locking pieces are matched with the bridges.

An LCD device comprises the aforementioned backlight module.

Because the present invention uses the independent locking pieces, the locking pieces can be selectively fixed and arranged in the positions for fixing the PCB on the backplane. Thus, the standardization and generalization design is achieved, and the cost is reduced; in addition, because a clamping structure is used between the locking piece and the PCB, compared with the modes of screw fixation, riveting fixation and the like, the clamping mode has high installation efficiency and is beneficial to productivity enhancement and further cost reduction.

### BRIEF DESCRIPTION OF FIGURES

FIG. 1 is an installation diagram of the present invention;

FIG. 2 is a schematic diagram of a first locking piece of the present invention;

FIG. 3 is a schematic diagram of a second locking piece of the present invention;

FIG. 4 is a schematic diagram of a third locking piece of the present invention;

FIG. 5 is a schematic diagram of a fourth locking piece of the present invention;

FIG. 6 is a schematic diagram of a locking piece fixed in a chute of the present invention;

FIG. 7 is a schematic diagram of a locking piece fixed in a mounting hole of the present invention; and

FIG. 8 is a schematic diagram of a locking piece applied in a frame type backplane of the present invention.

Wherein: 100. frame; 110. bracket; 120. bridge; 130. chute; 140. mounting hole; 300. locking piece; 310. conical peak; 320. buckling claw; 400. backplane; 500. PCB.

### DETAILED DESCRIPTION

The present invention will further be described in detail in accordance with the figures and the preferred examples.

As shown in FIG. 1, an LCD device, comprising: an LCD panel and a backlight module, wherein the bottom of the backlight module is provided with a backplane 400. The backplane 400 is provided with multiple locking pieces 300 for fixing a PCB 500. Each locking piece 300 is an independent accessory, and its root is provided with a fixed structure for fixing the locking piece 300 on the backplane 400. The fixed top of the locking piece 300 and the PCB is provided with a conical peak, and the bottom of the peak is extended with one or multiple elastic buckling claws 320, to form a clamping structure for fixing the PCB; the locking piece 300 can be integrally formed by plastics.

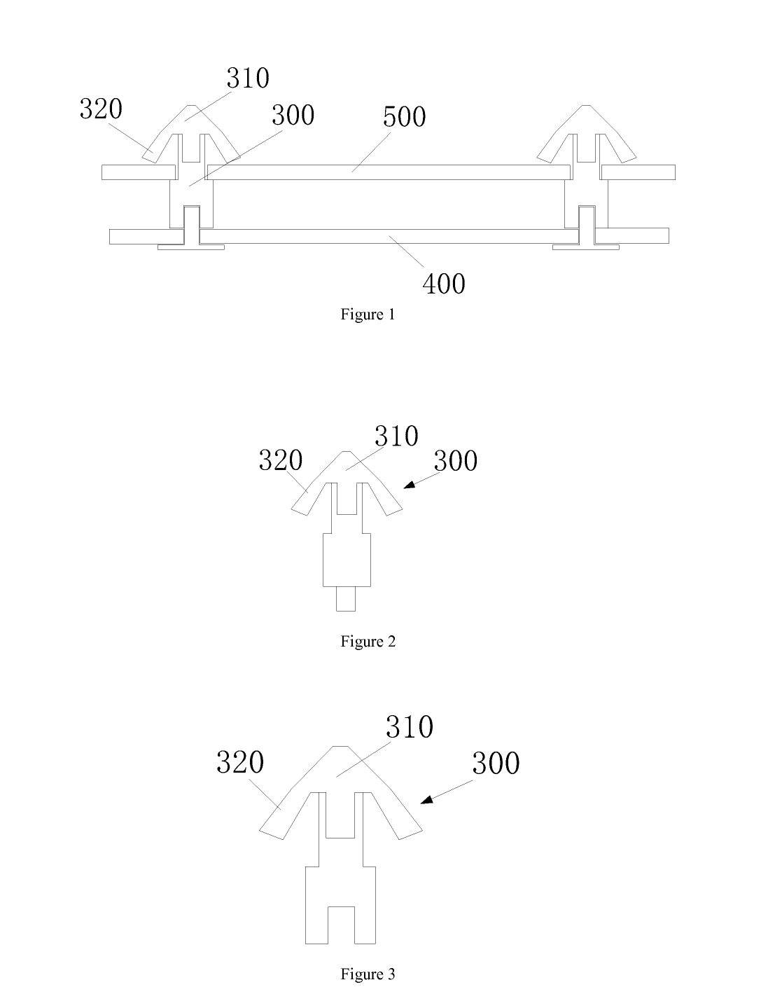

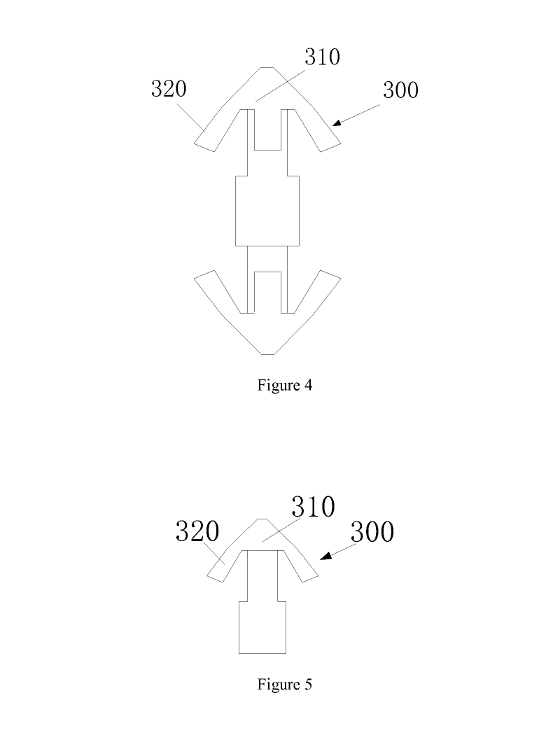

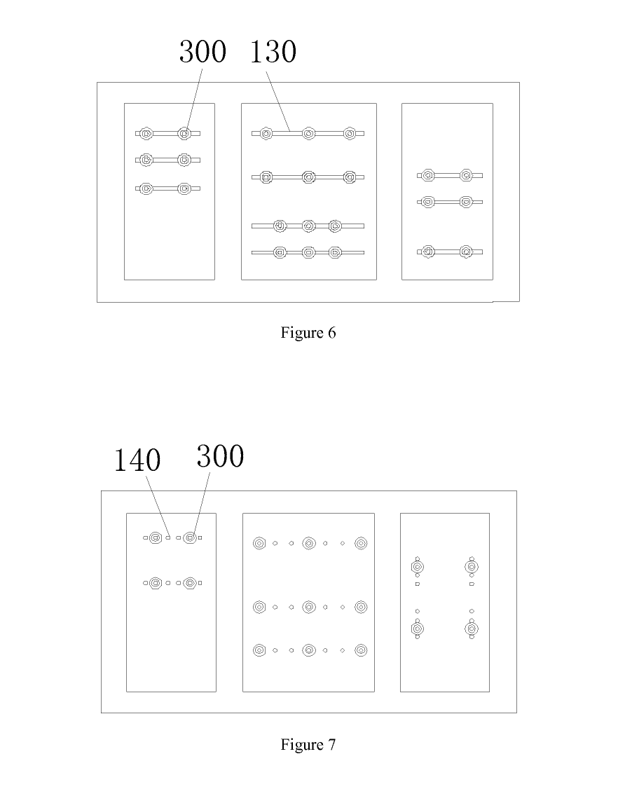

As shown in FIGS. 2 to 4, the locking piece 300 and the backplane 400 are provided with a fixed structure used for fixing the locking piece 300 on the backplane 400; the fixed structure can be in any form of riveting columns, screws or threaded holes, or the same clamping structure as that at the top; accordingly, the backplane 400 is provided positioning structure(s) for fixing the locking piece 300; the positioning structure can be in one or many forms of chutes 130, mounting holes 140 and the like. As shown in FIG. 6 to FIG. 8, the locking piece 300 is arranged on the backplane 400 by the positioning structure. Wherein, for a larger PCB, after the locking piece 300 is arranged on the edge and is fixed, the locking piece 300 is possibly unstable; the middle of the locking piece 300 may cave under the action of gravity; therefore, a part of the locking pieces can also be arranged; as shown in FIG. 5, the root of the locking piece 300 can be a plane which is unfixed with the backplane 400 and only fixed with the PCB 500 so as to purely support the PCB.

The locking pieces 300 can be used in the traditional integral backplane 400, and can be used in the backplane 400 of a frame 100 structure. For the traditional integral backplane 400, as shown in FIG. 7, the backplane 400 is formed by joining one or multiple plates, and the locking pieces 300 are fixed on the plate.

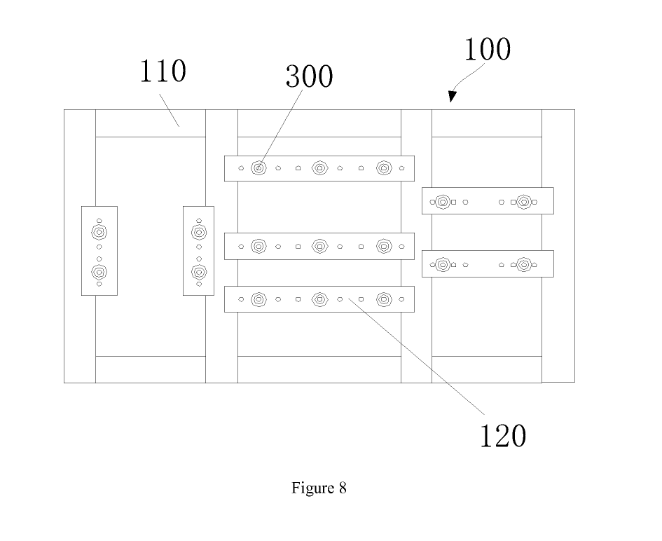

As shown in FIG. 6 and FIG. 8, for a backplane 400 of a frame 100 structure, the backplane 400 comprises a frame 100, and the frame comprises multiple mutually joined brackets 110. Bridges 120 are arranged among the brackets 110, and the locking pieces 300 are directly fixed on the bridges 120 or the brackets as required, or selectively fixed on the bridges 120 or fixed in the predetermined chutes of the brackets 110 or multiple mounting holes 140.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A locking piece for fixing the PCB on the backplane, comprising: a clamping structure arranged at the fixed top of said locking piece and said PCB; the root of said locking piece is provided with a fixed structure for fixing the locking piece on the backplane.

2. The locking piece for fixing the PCB on the backplane of claim 1, wherein the top of said locking piece is provided with a conical peak, and the bottom of said conical peak is extended with one or multiple elastic buckling claws.

3. The locking piece for fixing the PCB on the backplane of claim 2, wherein there are two elastic buckling claws.

4. The locking piece for fixing the PCB on the backplane of claim 1, wherein the structure of the fixed structure at the root of said locking piece is the same as that of said clamping structure at the top.

5. The locking piece for fixing the PCB on the backplane of claim 1, wherein the fixed structure at the root of said locking piece is a rivet integrally formed with the locking piece.

6. The locking piece for fixing PCB on backplane of claim 1, wherein the fixed structure at the root of said locking piece is an integrally formed screw.

7. The locking piece for fixing the PCB on the backplane of claim 1, wherein the fixed structure at the root of said locking piece is a threaded hole.

8. The locking piece for fixing the PCB on the backplane of claim 1, wherein said locking piece is integrally formed by plastics.

9. A backlight module, comprising: a backplane, a PCB, and locking piece(s) for fixing the PCB on the backplane of claim 1, wherein the fixed top of said locking piece and said PCB is provided with a clamping structure; the root of said locking piece is provided with a fixed structure for fixing the locking piece on said backplane; said backplane is provided with positioning structure(s) for fixing said locking piece, said locking piece is arranged on said backplane by the positioning structure, and said PCB is fixed on said locking piece.

10. The backlight module of claim 9, wherein the top of said locking piece is provided with a conical peak, and the bottom of said conical peak is extended with one or multiple buckling claws.

11. The backlight module of claim 10, wherein there are two elastic buckling claws.

12. The backlight module of claim 9, wherein the structure of the fixed structure at the root of said locking piece is the same as that of the clamping structure at the top.

13. The backlight module of claim 9, wherein said locking pieces are integrally formed by plastics.

14. The backlight module of claim 9, wherein said positioning structures are chutes, and said locking pieces are arranged on said backplane by the chutes.

15. The backlight module of claim 9, wherein said positioning structures are multiple standard mounting holes, and said locking pieces are selectively arranged on the backplane by the multiple mounting holes.

16. The backlight module of claim 9, wherein said backplane comprises a frame, and said frame comprises multiple mutually joined brackets. Bridges are arranged between said brackets, and said locking pieces are arranged on said bridges.

17. An LCD device, comprising: the backlight module of claim 9, wherein said backlight module comprises a backplane, a PCB, and locking piece(s) for fixing the PCB on the backplane. The fixed top of said locking piece and said PCB is provided with a clamping structure; the root of the locking piece is provided with a fixed structure for fixing the locking piece on the backplane; said backplane is provided with positioning structure(s) for fixing said locking piece, said locking piece is arranged on said backplane by the positioning structure, and said PCB is fixed on said locking piece.

18. The LCD device of claim 17, wherein the top of said locking piece is provided with a conical peak, and the bottom of said conical peak is extended with one or multiple elastic buckling claws.

19. The LCD device of claim 18, wherein there are two elastic buckling claws.

20. The LCD device of claim 17, wherein the structure of the fixed structure at the root of said locking piece is the same as that of said clamping structure at the top.

21. The LCD device of claim 17, wherein said locking pieces are integrally formed by plastics.
